(19) United States
(12) Patent Application Publication
(10) Pub. No.: US 2025/0308740 A1
(43) Pub. Date: Oct. 2, 2025

(54) METHOD OF MANUFACTURING MAGNETORESISTANCE EFFECT ELEMENT, MAGNETORESISTANCE EFFECT ELEMENT, MAGNETIC MULTILAYER FILM, MAGNETIC MEMORY, AND MAGNETIC SENSOR

(71) Applicant: TDK Corporation, Tokyo (JP)

(72) Inventors: Yugo ISHITANI, Tokyo (JP); Tomoyuki SASAKI, Tokyo (JP); Katsuyuki NAKADA, Tokyo (JP); Takeshi SEKI, Sendai-shi (JP); Koki TAKANASHI, Sendai-shi (JP)

(73) Assignee: TDK Corporation, Tokyo (JP)

(21) Appl. No.: 19/091,897

(22) Filed: Mar. 27, 2025

(30) Foreign Application Priority Data
Mar. 27, 2024 (JP) 2024-050652

(51) Int. Cl. H01F 10/32; G01R 33/09; H10B 61/00; H10N 50/01; H10N 50/10; H10N 50/85

(52) U.S. Cl. CPC H01F 10/329; G01R 33/09; H10B 61/20; H10N 50/01; H10N 50/10; H10N 50/85

(57) ABSTRACT

Provided is a magnetoresistance effect element including a first ferromagnetic layer, a second ferromagnetic layer, a nonmagnetic layer, and an underlayer. The nonmagnetic layer is located between the first ferromagnetic layer and the second ferromagnetic layer. The first ferromagnetic layer is located between the underlayer and the nonmagnetic layer. The underlayer contains Ta. The first ferromagnetic layer is represented by Co_{α}Fe_{β}X_{γ}Pt_{δ}, X is boron or carbon, and the relations of α+β+γ+δ=1, α≥β>0, and δ≤0.3 are satisfied. The first ferromagnetic layer has an easy axis of magnetization in a first direction in a plane orthogonal to the lamination direction, and an anisotropic magnetic field of the first ferromagnetic layer in a second direction is equal to or higher than 50 Oe. The second direction is orthogonal to the lamination direction and the first direction.

### BACKGROUND OF THE INVENTION

### Field of the Invention

The present invention relates to a method of manufacturing a magnetoresistance effect element, a magnetoresistance effect element, a magnetic multilayer film, a magnetic memory, and a magnetic sensor.

### Description of Related Art

A magnetoresistance effect element is an element of which the resistance value in the lamination direction changes due to the magnetoresistance effect. A magnetoresistance effect element includes two ferromagnetic layers and a nonmagnetic layer interposed therebetween. A magnetoresistance effect element in which a conductor is used for the nonmagnetic layer is referred to as a giant magnetoresistive (GMR) element, whereas a magnetoresistance effect element in which an insulating layer (tunnel barrier layer, barrier layer) is used for the nonmagnetic layer is referred to as a tunnel magnetoresistive (TMR) element. A magnetoresistance effect element can be used in a variety of applications such as magnetic sensors, high-frequency components, magnetic heads, and non-volatile random access memories (MRAMs).

The resistance value of the magnetoresistance effect element changes depending on the difference in the relative angle between the magnetization directions of two magnetic films. The magnetic memory records the resistance value of this magnetoresistance effect element as data. The magnetic sensor uses a change in the resistance value of this magnetoresistance effect element to perform sensing. When the resistance value of the magnetoresistance effect element changes unexpectedly under the influence of heat, an external magnetic field, or the like, this resistance change becomes noise in a magnetic memory or a magnetic sensor. In order to reduce noise, attempts have been made to improve the magnetization stability of the magnetoresistance effect element.

For example, Patent Document 1 discloses that the uniaxial magnetic anisotropy of a magnetic material is enhanced by orienting the crystal grain orientation of a nanocrystalline soft magnetic material. In addition, for example, Patent Document 2 discloses that the uniaxial magnetic anisotropy is enhanced by ordering a FePt alloy.

### PATENT DOCUMENTS

[Patent Document 1] Japanese Unexamined Patent Application, First Publication No. 2006-118040
[Patent Document 2] Japanese Unexamined Patent Application, First Publication No. 2004-311925

### SUMMARY OF THE INVENTION

The uniaxial magnetic anisotropy of a ferromagnetic layer is determined by various factors. For example, anisotropy caused by the shape of the ferromagnetic layer (shape magnetic anisotropy), anisotropy caused by the influence of the interface between the ferromagnetic layer and an adjacent layer (interface magnetic anisotropy), anisotropy caused by the crystal structure of the ferromagnetic layer (crystalline magnetic anisotropy), and anisotropy induced by a magnetic field during the growth of the ferromagnetic layer (induced magnetic anisotropy) are all factors that affect the magnetic anisotropy of the ferromagnetic layer. Depending on the application of the magnetoresistance effect element, there may be restrictions on its shape or the like, and it may be difficult to impart shape magnetic anisotropy to the ferromagnetic layer.

The present disclosure has been made in view of such circumstances, and an object thereof is to a provide a magnetoresistance effect element, a magnetic multilayer film, a magnetic memory, and a magnetic sensor which are less likely to be influenced by external forces such as heat or an external magnetic field and have high magnetization stability, and to provide methods of manufacturing the same.

In order to solve the above problems, the present disclosure provides the following means.
(1) A method of manufacturing a magnetoresistance effect element according to a first aspect includes: a lamination step of laminating an underlayer, a first ferromagnetic layer, a nonmagnetic layer, and a second ferromagnetic layer in this order; and a magnetic field application annealing step of performing annealing while applying a magnetic field in a first direction in a plane orthogonal to a lamination direction. The underlayer contains Ta. The first ferromagnetic layer is represented by Co_{α}Fe_{β}X_{γ}Pt_{δ}, X is boron or carbon, and the relations of α+β+γ+δ=1, α≥β>0, and δ≤0.3 are satisfied.
(2) In the method of manufacturing a magnetoresistance effect element according to the above aspect, an annealing temperature in the magnetic field application annealing step may be equal to or higher than 200° C.
(3) In the method of manufacturing a magnetoresistance effect element according to the above aspect, an annealing time in the magnetic field application annealing step may be equal to or longer than 30 minutes.
(4) In the method of manufacturing a magnetoresistance effect element according to the above aspect, a strength of the magnetic field applied in the magnetic field application annealing step may be equal to or higher than 1 kOe.
(5) In the method of manufacturing a magnetoresistance effect element according to the above aspect, γ may satisfy 0.05≤γ≤0.2.
(6) In the method of manufacturing a magnetoresistance effect element according to the above aspect, δ may satisfy 0.05≤δ≤0.3.
(7) In the method of manufacturing a magnetoresistance effect element according to the above aspect, the nonmagnetic layer may contain magnesium and oxygen.
(8) A magnetoresistance effect element according to a second aspect includes a first ferromagnetic layer, a second ferromagnetic layer, a nonmagnetic layer, and an underlayer. The nonmagnetic layer is located between the first ferromagnetic layer and the second ferromagnetic layer. The first ferromagnetic layer is located between the underlayer and the nonmagnetic layer. The underlayer contains Ta. The first ferromagnetic layer is represented by Co_{α}Fe_{β}X_{γ}Pt_{δ}, X is boron or carbon, and the relations of α+β+γ+δ=1, α≥β>0, and δ≤0.3 are satisfied. The first ferromagnetic layer has an easy axis of magnetization in a first direction in a plane orthogonal to a lamination direction, and an anisotropic magnetic field of the first ferromagnetic layer in a second direction is equal to or higher than 50 Oe. The second direction is orthogonal to the lamination direction and the first direction.
(9) In the magnetoresistance effect element according to the above aspect, γ may satisfy 0.05≤γ≤0.2.
(10) In the magnetoresistance effect element according to the above aspect, δ may satisfy 0.05≤δ≤0.3.
(11) In the magnetoresistance effect element according to the above aspect, the nonmagnetic layer may contain magnesium and oxygen.

(12) In the magnetoresistance effect element according to the above aspect, a thickness of the first ferromagnetic layer may be equal to or greater than 2 nm and equal to or less than 20 nm.
(13) In the magnetoresistance effect element according to the above aspect, the first ferromagnetic layer may have a uniaxial magnetic anisotropy energy equal to or greater than 2.0×10⁴ erg/cm.
(14) The magnetoresistance effect element according to the above aspect may further include a first electrode and a second electrode, wherein the first electrode may be connected to a first end of the underlayer, and the second electrode may be connected to a second end of the underlayer which is different from the first end.
(15) In the magnetoresistance effect element according to the above aspect, in a plan view from the lamination direction, a width of the first ferromagnetic layer in the first direction may be equal to or greater than 90% and equal to or less than 110% of a width of the first ferromagnetic layer in the second direction.
(16) A magnetic multilayer film according to a third aspect includes an underlayer and a first ferromagnetic layer. The underlayer is in contact with one surface of the first ferromagnetic layer. The underlayer contains Ta. The first ferromagnetic layer is represented by Co_{α}Fe_{β}X_{γ}Pt_{δ}, X is boron or carbon, and the relations of α+β+γ+δ=1, α≥β>0, 0.05≤γ≤0.2, and 0.05≤δ≤0.3 are satisfied. The first ferromagnetic layer has an easy axis of magnetization in a first direction in a plane orthogonal to a lamination direction, and an anisotropic magnetic field of the first ferromagnetic layer in a second direction is equal to or higher than 50 Oe. The second direction is orthogonal to the lamination direction and the first direction.
(17) A magnetic memory according to a fourth aspect includes the magnetoresistance effect element according to the above aspect.
(18) A magnetic sensor according to a fifth aspect includes the magnetoresistance effect element according to the above aspect.

The magnetoresistance effect element, the magnetic multilayer film, the magnetic memory, and the magnetic sensor according to the present disclosure make it possible to reduce the influence of external forces.

### BRIEF DESCRIPTION OF THE DRAWINGS

FIG. 1 is a cross-sectional view of a magnetoresistance effect element according to a first embodiment.

FIG. 2 is a plan view of the magnetoresistance effect element according to the first embodiment.

FIG. 3 is a diagram illustrating a method of manufacturing the magnetoresistance effect element according to the first embodiment.

FIG. 4 is a diagram illustrating a method of manufacturing the magnetoresistance effect element according to the first embodiment.

FIG. 5 is a schematic circuit diagram of a magnetic memory according to the present embodiment.

FIG. 6 is a cross-sectional view of a magnetoresistance effect element used in the magnetic memory according to the present embodiment.

FIG. 7 is a schematic circuit diagram of another example of the magnetic memory according to the present embodiment.

FIG. 8 is a schematic diagram of a magnetic sensor according to the present embodiment.

FIG. 9 is a schematic diagram of a magnetic multilayer film according to the present embodiment.

### DETAILED DESCRIPTION OF THE INVENTION

Hereinafter, the present embodiment will be described in detail with reference to the drawings as appropriate. In the drawings used in the following description, the characteristic parts may be shown in an enlarged scale for convenience in order to make the features easier to understand, and the dimensional ratios of components and the like may differ from the actual ones. The materials, dimensions, and the like exemplified in the following description are merely examples, and the present invention is not limited to these. They can be modified and implemented as appropriate within the scope of the effects of the present invention.

First, the directions are defined. The lamination direction of each layer is defined as a Z direction. One direction in a plane orthogonal to the Z direction is defined as an X direction. The X direction is an example of a first direction. The direction orthogonal to the Z direction and the X direction is defined as a Y direction. The Y direction is an example of a second direction. With respect to the Z direction, the direction from an underlayer toward a first ferromagnetic layer is defined as a +Z direction, and the opposite direction is defined as a −Z direction. Hereinafter, the +Z direction may be referred to as “up” and the −Z direction as “down.” Up and down do not necessarily coincide with the direction in which gravity is applied.

### Magnetoresistance Effect Element

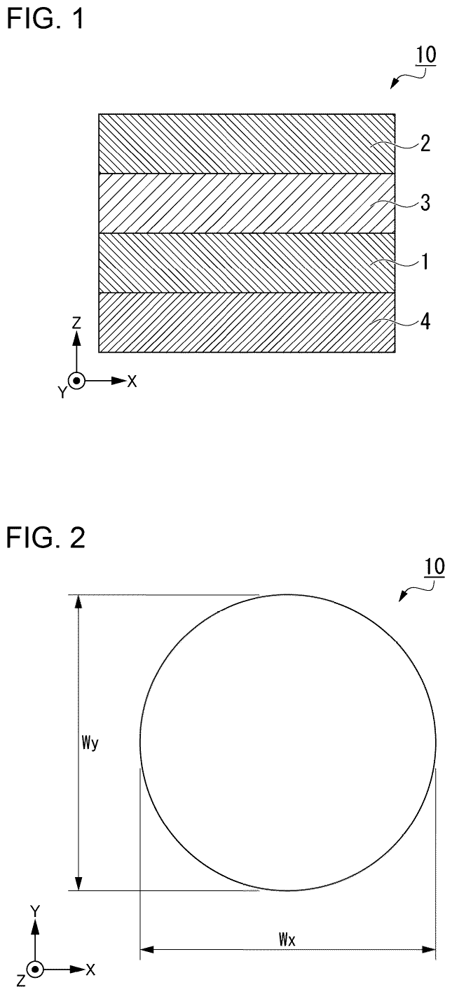

FIG. 1 is a cross-sectional view of a magnetoresistance effect element 10 according to a first embodiment. The magnetoresistance effect element 10 includes a first ferromagnetic layer 1, a second ferromagnetic layer 2, a nonmagnetic layer 3, and an underlayer 4.

The magnetoresistance effect element 10 outputs a change in the relative angle between the magnetization of the first ferromagnetic layer 1 and the magnetization of the second ferromagnetic layer 2 as a change in resistance value or a change in output voltage. The magnetization of the first ferromagnetic layer 1 is, for example, more mobile than the magnetization of the second ferromagnetic layer 2. In a case where a predetermined external force is applied, the direction of the magnetization of the second ferromagnetic layer 2 does not change (is fixed), and the direction of the magnetization of the first ferromagnetic layer 1 changes. The resistance value of the magnetoresistance effect element 10 changes as the direction of the magnetization of the first ferromagnetic layer 1 changes with respect to the direction of the magnetization of the second ferromagnetic layer 2. In this case, the second ferromagnetic layer 2 may be referred to as a magnetization fixed layer, and the first ferromagnetic layer 1 may be referred to as a magnetization free layer. In the following description, the second ferromagnetic layer 2 is a magnetization fixed layer, and the first ferromagnetic layer 1 is a magnetization free layer, but this relationship may be reversed.

The difference in mobility between the magnetization of the first ferromagnetic layer 1 and the magnetization of the second ferromagnetic layer 2 when a predetermined external force is applied is caused by the difference in coercive force between the first ferromagnetic layer 1 and the second ferromagnetic layer 2. For example, when the thickness of the second ferromagnetic layer 2 is greater than the thickness of the first ferromagnetic layer 1, the coercive force of the second ferromagnetic layer 2 is often larger than the coercive force of the first ferromagnetic layer 1. In addition, for example, by configuring the second ferromagnetic layer 2 to have a synthetic antiferromagnetic structure (SAF structure), the coercive force of the second ferromagnetic layer 2 can be made larger than the coercive force of the first ferromagnetic layer 1. The synthetic antiferromagnetic structure is composed of two magnetic layers with a spacer layer interposed therebetween. When the two magnetic layers with a spacer layer interposed therebetween are antiferromagnetically coupled to each other, the coercive force of the magnetic layers becomes larger than when these layers are not antiferromagnetically coupled to each other. The spacer layer contains at least one element selected from the group consisting of, for example, Ru, Ir, and Rh.

The first ferromagnetic layer 1 is located between the underlayer 4 and the nonmagnetic layer 3. The first ferromagnetic layer 1 is a ferromagnetic layer represented by Co_{α}Fe_{β}X_{γ}Pt_{δ}, which satisfies α+β+γ+δ=1. Co_{α}Fe_{β}X_{γ}Pt_{δ} has an induced magnetic anisotropy in the in-plane direction. The first ferromagnetic layer 1 has, for example, a cubic crystal (bcc) structure.

Here, a represents the composition ratio of Co, and β represents the composition ratio of Fe, where a and B satisfy α≥β>0. In the case of α>β, the first ferromagnetic layer 1 serves as a Co-rich ferromagnetic layer. Co is a material that is likely to have a hexagonal crystal structure and is more likely to exhibit uniaxial anisotropy than Fe, which is likely to have a cubic crystal structure. Therefore, the first ferromagnetic layer 1, in which the composition ratio of Co is richer than the composition ratio of Fe, exhibits large uniaxial magnetic anisotropy of the first ferromagnetic layer 1.

X is boron (B) or carbon (C), and is preferably boron (B). In addition, γ represents the composition ratio of X, where γ preferably satisfies 0.05≤γ≤0.2. In a case where γ satisfies this range, the lattice matching between the first ferromagnetic layer 1 and the nonmagnetic layer 3 is improved, and the uniaxial magnetic anisotropy of the first ferromagnetic layer 1 is increased. The degree of lattice matching between the first ferromagnetic layer 1 and the nonmagnetic layer 3 is, for example, within 10%, and preferably 5%. The degree of lattice matching represents the degree of deviation of the lattice constant of one of two layers with an interface interposed therebetween when the lattice constant of the other layer is taken as the reference. As the degree of lattice matching becomes lower, the lattice matching between two layers with an interface interposed therebetween becomes higher. When the lattice constant of the nonmagnetic layer 3 is taken as a reference, the lattice constant of the first ferromagnetic layer 1 is, for example, equal to or greater than 90% and equal to or less than 110% of the lattice constant of the nonmagnetic layer 3.

Here, δ represents the composition ratio of Pt. The relation of δ≤0.3 is satisfies. The relation of δ=0 may be established. In the case of δ=0, the first ferromagnetic layer 1 is represented by Co_{α}Fe_{β}X_{γ}. In addition, δ preferably satisfies 0.05≤δ≤0.3. In the case of δ>0, the uniaxial magnetic anisotropy of the first ferromagnetic layer 1 becomes large. The uniaxial magnetic anisotropy of the first ferromagnetic layer 1 is thought to have increased due to the inclusion of Pt, which has a large spin-orbit interaction, in the first ferromagnetic layer 1.

The first ferromagnetic layer 1 has an easy axis of magnetization oriented in the X direction. The anisotropic magnetic field of the first ferromagnetic layer 1 in the Y direction is equal to or higher than 50 Oe. The anisotropic magnetic field of the first ferromagnetic layer 1 in the Y direction is preferably equal to or higher than 70 Oe, more preferably equal to or higher than 100 Oe, further preferably equal to or higher than 200 Oe, and particularly preferably equal to or greater than 280 Oe. The first ferromagnetic layer 1 has a large magnetic anisotropy in one direction within the XY plane. This large magnetic anisotropy is realized by performing annealing in a magnetic field which will be described later.

The thickness of the first ferromagnetic layer 1 is, for example, equal to or greater than 2 nm and equal to or less than 20 nm. When the thickness of the first ferromagnetic layer 1 is in this range, the uniaxial magnetic anisotropy of the first ferromagnetic layer 1 becomes large.

FIG. 2 is a plan view of the magnetoresistance effect element 10 according to the first embodiment as viewed in the Z direction. The plan-view shape of the first ferromagnetic layer 1 viewed in the Z direction is, for example, circular or rectangular. The plan-view shape of the first ferromagnetic layer 1 viewed in the Z direction is, for example, isotropic. The width Wx of the first ferromagnetic layer 1 in the X direction is, for example, equal to or greater than 90% and equal to or less than 110% of the width Wy of the first ferromagnetic layer 1 in the Y direction. In addition, the width of the first ferromagnetic layer 1 in its major axis direction is, for example, equal to or less than 110% of the width of the first ferromagnetic layer 1 in its minor axis direction. In a case where the plan-view shape is isotropic, the shape magnetic anisotropy hardly acts on the first ferromagnetic layer 1. By performing annealing in a magnetic field which will be described later, large uniaxial magnetic anisotropy can be realized even in the first ferromagnetic layer 1 of which the plan-view shape viewed in the Z direction is approximately isotropic.

The plan-view shape of the first ferromagnetic layer 1 viewed in the Z direction may be anisotropic. For example, the width Wx of the first ferromagnetic layer 1 in the X direction may be, for example, more than 110% of the width Wy of the first ferromagnetic layer 1 in the Y direction. The width of the first ferromagnetic layer 1 in its major axis direction may be, for example, more than 110% of the width of the first ferromagnetic layer 1 in its minor axis direction, and is preferably equal to or greater than 150%. When the major axis of the first ferromagnetic layer 1 in the X direction, the shape magnetic anisotropy acts on the magnetization of the first ferromagnetic layer 1, and thus it is possible to further enhance the uniaxial magnetic anisotropy of the first ferromagnetic layer 1. In this case, the anisotropic magnetic field of the first ferromagnetic layer 1 in the Y direction can also be set to be equal to or higher than 350 Oe.

The uniaxial magnetic anisotropy energy of the first ferromagnetic layer 1 is, for example, equal to or greater than 2.0×10⁴ erg/cm, preferably equal to or greater than 5.0×10⁴ erg/cm, and more preferably equal to or greater than 1.0×10⁵ erg/cm.

The second ferromagnetic layer 2 faces the first ferromagnetic layer 1 with the nonmagnetic layer 3 interposed therebetween. Similarly to the first ferromagnetic layer 1, the second ferromagnetic layer 2 is an in-plane magnetized film in which the magnetization is oriented in one direction within the XY plane.

The second ferromagnetic layer 2 is, for example, a metal selected from the group consisting of Cr, Mn, Co, Fe, and Ni, an alloy containing one or more metals selected from this group, or an alloy containing one or a plurality of metals selected from these and at least one or more elements of B, C, and N. The second ferromagnetic layer 2 is, for example, Co—Fe, Co—Fe—B, Ni—Fe, a Co—Ho alloy (CoHO₂), or a Sm—Fe alloy (SmFe₁₂). The second ferromagnetic layer 2 may be a ferromagnetic material having the same composition as the first ferromagnetic layer 1. In addition, the second ferromagnetic layer 2 may also be a Heusler alloy.

The nonmagnetic layer 3 is located between the first ferromagnetic layer 1 and the second ferromagnetic layer 2. The nonmagnetic layer 3 has a thickness, for example, in the range of 1 nm to 10 nm. The nonmagnetic layer 3 inhibits magnetic coupling between the first ferromagnetic layer 1 and the second ferromagnetic layer 2.

The nonmagnetic layer 3 is made of, for example, a nonmagnetic insulator. The nonmagnetic insulator is, for example, Al₂O₃, SiO₂, MgO, MgAl₂O₄, or a material in which part of these Al, Si, and Mg is replaced with Zn, Be, or the like. These materials have a wide bandgap and excellent insulating properties. The nonmagnetic layer 3 contains, for example, magnesium and oxygen. The nonmagnetic layer 3 is made of, for example, MgO or MgAl₂O₄. The nonmagnetic layer 3 containing magnesium and oxygen has excellent lattice matching between the first ferromagnetic layer 1 and the second ferromagnetic layer 2 which are adjacent to the nonmagnetic layer 3. The degree of lattice matching between the second ferromagnetic layer 2 and the nonmagnetic layer 3 is, for example, within 10%, and preferably within 5%.

The nonmagnetic layer 3 may be a nonmagnetic metal or semiconductor. The nonmagnetic metal is, for example, a metal or alloy containing any element selected from the group consisting of Cu, Au, Ag, Al, and Cr. The metal or alloy containing these elements has excellent electrical conductivity and lowers the area resistance (hereinafter referred to as RA) of the magnetoresistance effect element 10. The nonmagnetic semiconductor is, for example, Si, Ge, CuInSe₂, CuGaSe₂, Cu(In, Ga)Se₂, or the like.

The underlayer 4 interposes the first ferromagnetic layer 1 together with the nonmagnetic layer 3. The first ferromagnetic layer 1 is laminated on, for example, the underlayer 4. The underlayer 4 enhances the crystal orientation of the first ferromagnetic layer 1 and the second ferromagnetic layer 2.

The underlayer 4 contains Ta. The underlayer 4 may be made of Ta. The underlayer 4 containing Ta absorbs boron or carbon contained in the first ferromagnetic layer 1 by performing annealing in a magnetic field which will be described later. When the boron or carbon contained in the first ferromagnetic layer 1 is absorbed, the crystallinity of the first ferromagnetic layer 1 is improved, and the uniaxial magnetic anisotropy of the first ferromagnetic layer 1 is improved.

### Method of Manufacturing Magnetoresistance Effect Element

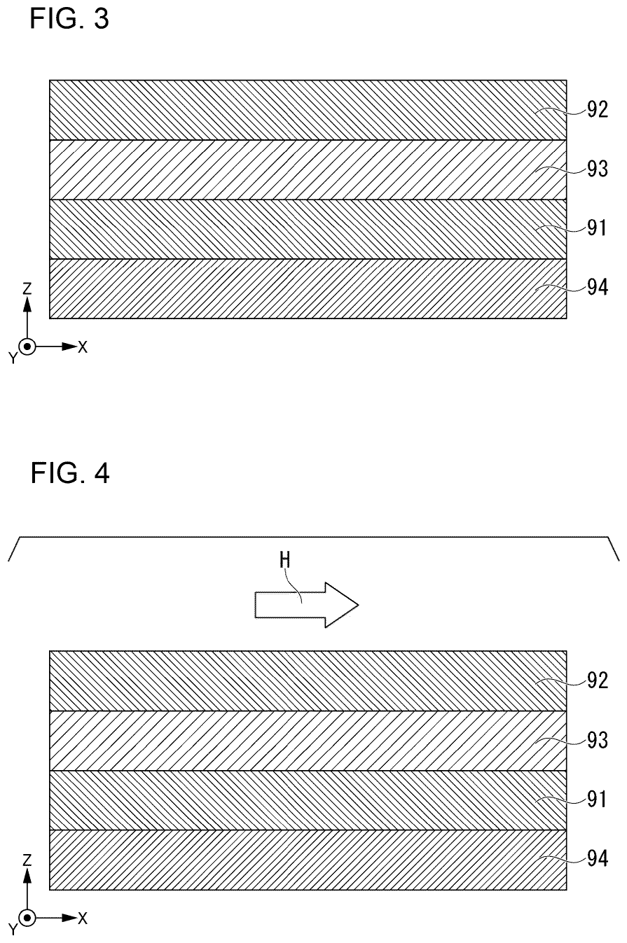

FIGS. 3 and 4 are diagrams illustrating a method of manufacturing the magnetoresistance effect element 10 according to the first embodiment. The method of manufacturing the magnetoresistance effect element 10 includes a lamination step, a magnetic field application annealing step, and a processing step.

FIG. 3 is a diagram illustrating a lamination step. In the lamination step, an underlayer 94, a first ferromagnetic layer 91, a nonmagnetic layer 93, and a second ferromagnetic layer 92 are laminated in this order. The lamination of each layer can be performed using sputtering, chemical vapor deposition (CVD), electron beam deposition (EB deposition), atomic laser deposition, or the like.

The underlayer 94 corresponds to the underlayer 4 and contains Ta. The first ferromagnetic layer 91 corresponds to the first ferromagnetic layer 1 and is represented by Co_{α}Fe_{β}X_{γ}Pt_{δ}. In the composition formula, α, β, γ, δ, and X are the same as those of the first ferromagnetic layer 1. The nonmagnetic layer 93 corresponds to the nonmagnetic layer 3 and contains, for example, magnesium and oxygen. The second ferromagnetic layer 92 corresponds to the second ferromagnetic layer 2.

The first ferromagnetic layer 91 before the magnetic field application annealing step is an in-plane magnetized film under the influence of shape magnetic anisotropy. On the other hand, the first ferromagnetic layer 91 before the magnetic field application annealing step has magnetization oriented isotropically in-plane and has no uniaxial magnetic anisotropy.

FIG. 4 is a diagram illustrating a magnetic field application annealing step. In the magnetic field application annealing step, annealing is performed while a magnetic field H is applied in the X direction.

In the magnetic field application annealing step, the annealing temperature is preferably equal to or higher than 200° C. When the annealing temperature during the application of the magnetic field H is high, the crystals of the first ferromagnetic layer 91 are more likely to move under the influence of the magnetic field H, and the magnetization is more likely to be oriented in one direction.

In the magnetic field application annealing step, the annealing time is preferably equal to or longer than 30 minutes, and the strength of the magnetic field is preferably equal to or higher than 1 kOe. Applying a magnetic field of sufficient strength facilitates the orientation of the magnetization in one direction.

In the first ferromagnetic layer 1 in the magnetic field application annealing step, the easy axis of magnetization is the X direction even at a point in time before the processing step. The first ferromagnetic layer 1 has an anisotropic magnetic field equal to or higher than 50 Oe in the Y direction through the magnetic field application annealing step.

Next, the processing step is performed. The processing step can be performed using, for example, photolithography or the like. The magnetoresistance effect element 10 is obtained by processing a multilayer film into a predetermined shape. The underlayer 94 becomes the underlayer 4, the first ferromagnetic layer 91 becomes the first ferromagnetic layer 1, the nonmagnetic layer 93 becomes the nonmagnetic layer 3, and the second ferromagnetic layer 92 becomes the second ferromagnetic layer 2. Here, a case where the processing step is performed after the magnetic field application annealing step has been exemplified, but the processing step may be performed before the magnetic field application annealing step.

The magnetoresistance effect element 10 according to the present embodiment has high stability because the magnetization of the first ferromagnetic layer 1 is strongly oriented in the X direction. The magnetoresistance effect element 10 according to the present embodiment is less likely to undergo unexpected magnetization reversal due to an external force even in a case where heat is applied or a case where an external magnetic field is applied.

The magnetoresistance effect element 10 according to the present embodiment can be used as, for example, a magnetic memory or a magnetic sensor.

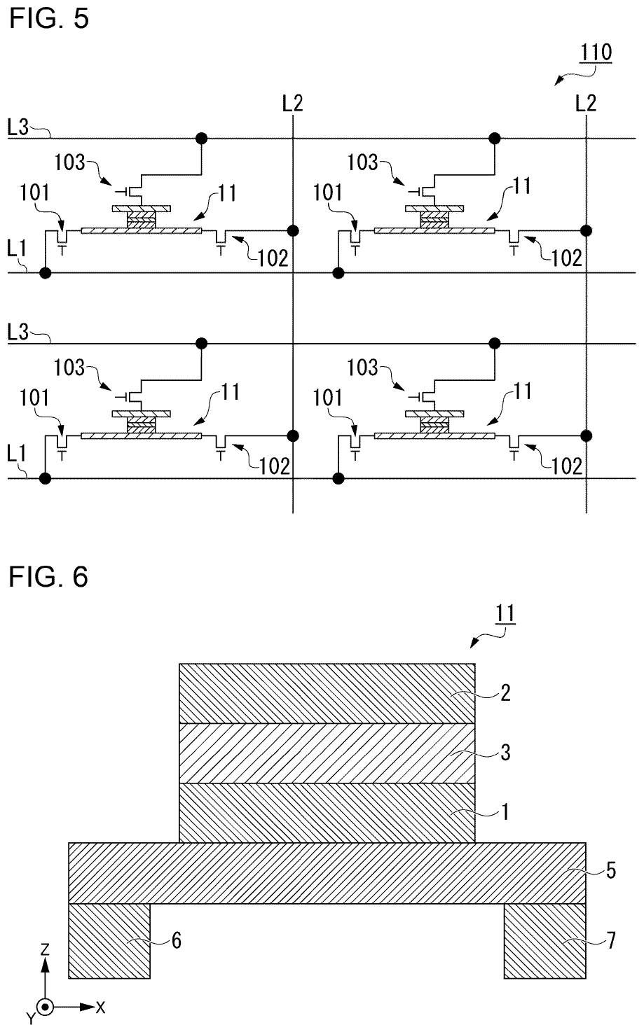

FIG. 5 is a schematic circuit diagram of a magnetic memory 110 according to the present embodiment. The magnetic memory 110 includes a plurality of magnetoresistance effect elements 11, a plurality of first wirings L1, a plurality of second wirings L2, a plurality of third wirings L3, a plurality of first switches 101, a plurality of second switches 102, and a plurality of third switches 103. The magnetic memory 110 has, for example, the magnetoresistance effect elements 11 arranged in an array.

Each of the first wirings L1 electrically connects a power supply and one or more magnetoresistance effect elements 11. Each of the second wirings L2 is a wiring used for both writing and reading data. Each of the second wirings L2 electrically connects a reference potential and one or more magnetoresistance effect elements 11. The reference potential is, for example, a ground. Each of the third wirings L3 electrically connects a power supply and one or more magnetoresistance effect elements 11. The power supply is connected to the magnetic memory 110 when in use.

Each of the magnetoresistance effect elements 11 is connected to a first switch 101, a second switch 102, and a third switch 103. The first switch 101 is connected between the magnetoresistance effect element 11 and the first wiring L1. The second switch 102 is connected between the magnetoresistance effect element 11 and the second wiring L2. The third switch 103 is connected between the magnetoresistance effect element 11 and the third wiring L3. Any of the first switch 101, the second switch 102, and the third switch 103 may be shared by the magnetoresistance effect elements 11 connected to the same wiring. Each of the first switch 101, the second switch 102, and the third switch 103 can be implemented using a known element such as, for example, a transistor.

FIG. 6 is a cross-sectional view of the magnetoresistance effect element 11 used in the magnetic memory 110 according to the present embodiment. The magnetoresistance effect element 10 includes the first ferromagnetic layer 1, the second ferromagnetic layer 2, the nonmagnetic layer 3, an underlayer 5, a first electrode 6, and a second electrode 7. The magnetoresistance effect element 11 is a magnetoresistance effect element that performs magnetization reversal using spin orbit torque (SOT), and may be referred to a spin orbit torque-type magnetoresistance effect element, a spin injection-type magnetoresistance effect element, or a spin current magnetoresistance effect element.

The first ferromagnetic layer 1, the second ferromagnetic layer 2, and the nonmagnetic layer 3 are the same as those described above. The upper surface of the second ferromagnetic layer 2 is connected to the third wiring L3. The underlayer 5 is the same as the underlayer 4, except that the length in the X direction is longer than the length in the Y direction. The first electrode 6 is connected to a first end of the underlayer 5. In addition, the first electrode 6 is connected to the first wiring L1. The second electrode 7 is connected to a second end of the underlayer 5. In addition, the second electrode 7 is connected to the second wiring L2. The first electrode 6 and the second electrode 7 are conductors.

The magnetoresistance effect element 11 is an element that records and stores data. The magnetoresistance effect element 11 records data on the basis of its resistance value in the z direction. The resistance value of the magnetoresistance effect element 11 in the z direction changes as a write current is applied along the underlayer 5 and spins are injected from the underlayer 5 into the first ferromagnetic layer 1. The resistance value of the magnetoresistance effect element 11 in the z direction can be read out by applying a readout current between the second ferromagnetic layer 2 and the first electrode 6 or the second electrode 7.

Spins are injected from the underlayer 5 into the first ferromagnetic layer 1. The underlayer 5 induces a spin current through spin-orbit interaction and the interface Rashba effect, and injects spins into the first ferromagnetic layer 1. The underlayer 5 applies, for example, spin orbit torque (SOT) to the magnetization of the first ferromagnetic layer 1 enough to reverse the magnetization of the first ferromagnetic layer 1.

The spin Hall effect is a phenomenon in which, when an electric current is caused to flow, a spin current is induced in a direction orthogonal to the direction of the flow of the electric current on the basis of spin-orbit interaction. The spin Hall effect shares a common feature with the ordinary Hall effect in that the direction of movement of moving electric charges (electrons) can be bent. In the ordinary Hall effect, the direction of movement of charged particles moving in a magnetic field can be bent by the Lorentz force. On the other hand, in the spin Hall effect, the direction of movement of spins can be bent simply by the movement of electrons (simply by the flow of a current) even in the absence of a magnetic field.

For example, when a current flows along the underlayer 5, first spins polarized in one direction and second spins polarized in the opposite direction to the first spins are each bent by the spin Hall effect in a direction orthogonal to the direction of the flow of the current. For example, the first spins polarized in the −y direction are bent in the +z direction from the x direction which is the direction of travel, and the second spins polarized in the +y direction are bent in the −z direction from the x direction which is the direction of travel.

In a nonmagnetic material (a material which is not ferromagnetic), the number of electrons of the first spin and the number of electrons of the second spin generated by the spin Hall effect are equal to each other. That is, the number of electrons of the first spin in the +z direction and the number of electrons of the second spin in the −z direction are equal to each other. The first spin and the second spin flow in a direction that resolves the uneven distribution of the spins. In the movement of the first spin and the second spin in the z direction, the flows of electric charges cancel each other out, and thus the amount of current becomes zero. A spin current which is not accompanied by a current is specifically referred to as a pure spin current.

Denoting the flow of electrons of the first spin as J_{↑}, the flow of electrons of the second spin as J_{↓}, and the spin current as J_{S}, the spin current is defined by J_{S}=J_{↑}−J_{↓}. The spin current J_{S} is generated in the z direction. The first spins are injected from the underlayer 5 into the first ferromagnetic layer 1.

The magnetization of the first ferromagnetic layer 1 undergoes spin orbit torque (SOT) due to the injected spins, which leads to a change in its orientation direction. The underlayer 5 contains Ta. Ta exhibits strong spin-orbit interaction, which makes it possible for a large number of spins to be injected into the first ferromagnetic layer 1.

The magnetoresistance effect element 11 has a high stability of magnetization because the first ferromagnetic layer 1 is oriented in the in-plane X direction. Therefore, the magnetic memory 110 having this magnetoresistance effect element 11 exhibits excellent reliability because data is less likely to be rewritten by an unexpected external force.

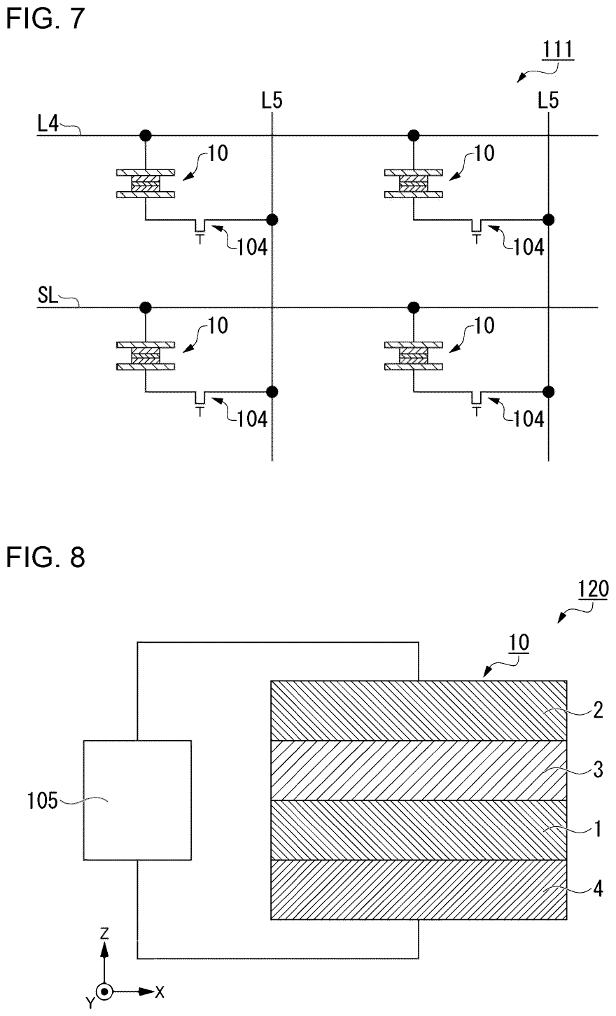

In addition, FIG. 7 is a schematic circuit diagram of another example of the magnetic memory according to the present embodiment. A magnetic memory 111 illustrated in FIG. 7 includes a plurality of magnetoresistance effect elements 10, a plurality of fourth wirings L4, a plurality of fifth wirings L5, and a plurality of fourth switches 104.

The magnetoresistance effect elements 10 are arranged, for example, in a matrix. Each of the magnetoresistance effect elements 10 is connected to the fourth wiring LA and the fifth wiring L5.

The flow of current to the magnetoresistance effect element 10 is controlled by the fourth switch 104. The magnetoresistance effect element 10 writes and reads out data by turning on the fourth switch 104. The magnetoresistance effect element 10 writes data using spin transfer torque as a current flows in the lamination direction. The fourth switch 104 is the same as the first switch 101 and the like.

Since the magnetic memory 111 has the magnetoresistance effect element 10 including the first ferromagnetic layer 1 in which magnetization is strongly oriented in one in-plane direction, the magnetic memory exhibits excellent reliability because data is less likely to be rewritten by an unexpected external force.

FIG. 8 is a schematic diagram of a magnetic sensor 120 according to the present embodiment. The magnetic sensor 120 includes the magnetoresistance effect element 10 and a detector 105.

The detector 105 detects a change in the resistance of the magnetoresistance effect element 10. A first end of the detector 105 is connected to the underlayer 4, and a second end of the detector 105 is connected to the second ferromagnetic layer 2. When a magnetic field to be detected is applied to the first ferromagnetic layer 1 of the magnetoresistance effect element 10, the magnetization of the first ferromagnetic layer 1 undergoes precession. When the magnetization of the first ferromagnetic layer 1 undergoes precession, the relative angle between the magnetization of the first ferromagnetic layer 1 and the magnetization of the second ferromagnetic layer 2 changes, resulting in a change in the resistance value of the magnetoresistance effect element 10. For example, in a case where the magnetic sensor 120 detects a leakage magnetic field from the magnetization written in a magnetic recording medium, the magnetic sensor 120 functions as a magnetic head.

Since the magnetic sensor 120 has the magnetoresistance effect element 10 including the first ferromagnetic layer 1 in which magnetization is strongly oriented in one in-plane direction, the magnetic sensor exhibits excellent reliability because data is less likely to be rewritten by an unexpected external force.

### Magnetic Multilayer Film

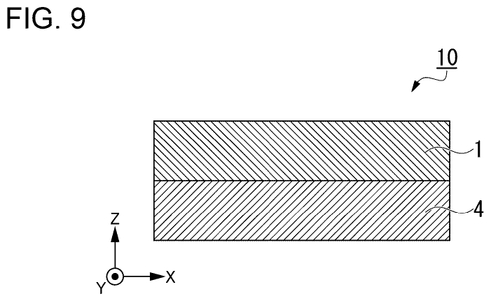

FIG. 9 is a cross-sectional view of a magnetic multilayer film according to the present embodiment. A magnetic multilayer film 20 includes the underlayer 4 and the first ferromagnetic layer 1. The first ferromagnetic layer 1 is laminated on the underlayer 4. An intermediate layer may be provided between the first ferromagnetic layer 1 and the underlayer 4.

The first ferromagnetic layer 1 and the underlayer 4 are the same as those in the magnetoresistance effect element 10. The underlayer 4 may contain Ta or be made of Ta. The first ferromagnetic layer 1 is represented by Co_{α}Fe_{β}X_{γ}Pt_{δ}, where X is boron or carbon, and the relations of α+β+γ+δ=1, α≥β>0, 0.05≤γ≤0.2, and 0.05≤δ≤0.3 are satisfied. The first ferromagnetic layer has an easy axis of magnetization in the X direction, and the anisotropic magnetic field of the first ferromagnetic layer in the Y direction is equal to or higher than 50 Oe.

The magnetic multilayer film according to the present embodiment has a high stability of magnetization because the first ferromagnetic layer 1 is strongly oriented in one in-plane direction (X direction).

The magnetic multilayer film according to the present embodiment can also be used as an anisotropic magnetic sensor, or an optical element utilizing the magnetic Kerr effect or the magnetic Faraday effect.

Although several embodiments have been described so far to illustrate preferred aspects of the present invention, the present invention is not limited to these embodiments. For example, the characteristic configurations of each embodiment may be applied to other embodiments.

### EXAMPLE

### Example 1

In Example 1, a magnetoresistance effect element satisfying the following configuration was fabricated.
Underlayer: Ta
First ferromagnetic layer: CO_{0.4}Fe_{0.4}B_{0.2} with a thickness of 3 nm
Nonmagnetic layer: MgO
Second ferromagnetic layer: Co_{0.2}Fe_{0.6}B_{0.2}
Plan-view shape: square with lengths of 10 mm in the X and Y directions

The magnetoresistance effect element according to Example 1 was fabricated by laminating an underlayer, a first ferromagnetic layer, a nonmagnetic layer, and a second ferromagnetic layer in this order, performing magnetic field application annealing on these layers, and then processing these layers into a predetermined shape. The magnetic field application annealing was performed under the following conditions: an annealing temperature of 350° C., an annealing time of 60 minutes, and a magnetic field strength of 10 kOe applied during annealing.

The magnetization of the first ferromagnetic layer of the magnetoresistance effect element in Example 1 was oriented in the in-plane X direction under no magnetic field. The anisotropic magnetic field of the first ferromagnetic layer in the Y direction was 50 Oe. In addition, the uniaxial magnetic anisotropy energy of the first ferromagnetic layer was 3.6×10⁴ erg/cm.

### Example 2

Example 2 differs from Example 1 in that the composition of the first ferromagnetic layer was Co_{0.5}Fe_{0.3}B_{0.2}. Example 2 differs from Example 1 in that the relation of α>β is established. The other conditions were the same as in Example 1, and the same measurements as in Example 1 were performed.

The magnetization of the first ferromagnetic layer of the magnetoresistance effect element in Example 2 was oriented in the in-plane X direction under no magnetic field. The anisotropic magnetic field of the first ferromagnetic layer in the Y direction was 63 Oe. In addition, the uniaxial magnetic anisotropy energy of the first ferromagnetic layer was 4.5×10⁴ erg/cm.

### Comparative Example 1

Comparative Example 1 differs from Example 1 in that the composition of the first ferromagnetic layer was Co_{0.2}Fe_{0.6}B_{0.2}. Comparative Example 1 differs from Example 1 in that the relation of α<β is established. The other conditions were the same as in Example 1, and the same measurements as in Example 1 were performed.

The magnetization of the first ferromagnetic layer of the magnetoresistance effect element in Comparative Example 1 was oriented in the in-plane X direction under no magnetic field. The anisotropic magnetic field of the first ferromagnetic layer in the Y direction was 25 Oe. In addition, the uniaxial magnetic anisotropy energy of the first ferromagnetic layer was 1.7×10⁴ erg/cm.

### Example 3

Example 3 differs from Example 1 in that the composition of the first ferromagnetic layer was Co_{0.36}Fe_{0.36}B_{0.13}Pt_{0.15}. Example 3 differs from Example 1 in that the first ferromagnetic layer 1 contains Pt with δ=0.15. The other conditions were the same as in Example 1, and the same measurements as in Example 1 were performed.

The magnetization of the first ferromagnetic layer of the magnetoresistance effect element in Example 3 was oriented in the in-plane X direction under no magnetic field. The anisotropic magnetic field of the first ferromagnetic layer in the Y direction was 64 Oe. In addition, the uniaxial magnetic anisotropy energy of the first ferromagnetic layer was 3.6×10⁴ erg/cm.

### Example 4

Example 4 differs from Example 3 in the composition of the first ferromagnetic layer was Co_{0.33}Fe_{0.33}B_{0.13}Pt_{0.21}. Example 4 differs from Example 3 in that the relation of δ=0.21 is established. The other conditions were the same as in Example 3, and the same measurements as in Example 3 were performed.

The magnetization of the first ferromagnetic layer of the magnetoresistance effect element in Example 4 was oriented in the in-plane X direction under no magnetic field. The anisotropic magnetic field of the first ferromagnetic layer in the Y direction was 127 Oe. In addition, the uniaxial magnetic anisotropy energy of the first ferromagnetic layer was 6.9×10⁴ erg/cm.

### Example 5

Example 5 differs from Example 3 in that the composition of the first ferromagnetic layer was Co_{0.31}Fe_{0.31}B_{0.12}Pt_{0.26}. Example 5 differs from Example 3 in that the relation of δ=0.26 is established. The other conditions were the same as in Example 3, and the same measurements as in Example 3 were performed.

The magnetization of the first ferromagnetic layer of the magnetoresistance effect element in Example 5 was oriented in the in-plane X direction under no magnetic field. The anisotropic magnetic field of the first ferromagnetic layer in the Y direction was 145 Oe. In addition, the uniaxial magnetic anisotropy energy of the first ferromagnetic layer was 6.3×10⁴ erg/cm.

### Example 6

Example 6 differs from Example 2 in that the composition of the first ferromagnetic layer was Co_{0.46}Fe_{0.27}B_{0.14}Pt_{0.13}. Example 6 differs from Example 2 in that the first ferromagnetic layer 1 contains Pt with δ=0.13. The other conditions were the same as in Example 2, and the same measurements as in Example 2 were performed.

The magnetization of the first ferromagnetic layer of the magnetoresistance effect element in Example 6 was oriented in the in-plane X direction under no magnetic field. The anisotropic magnetic field of the first ferromagnetic layer in the Y direction was 100 Oe. In addition, the uniaxial magnetic anisotropy energy of the first ferromagnetic layer was 5.7×10⁴ erg/cm.

### Example 7

Example 7 differs from Example 6 in that the composition of the first ferromagnetic layer was Co_{0.41}Fe_{0.26}X_{0.13}Pt_{0.20}. Example 7 differs from Example 6 in that the relation of δ=0.20 is established. The other conditions were the same as in Example 6, and the same measurements as in Example 6 were performed.

The magnetization of the first ferromagnetic layer of the magnetoresistance effect element in Example 7 was oriented in the in-plane X direction under no magnetic field. The anisotropic magnetic field of the first ferromagnetic layer in the Y direction was 125 Oe. In addition, the uniaxial magnetic anisotropy energy of the first ferromagnetic layer was 6.6×10⁴ erg/cm.

### Example 8

Example 8 differs from Example 6 in that the composition of the first ferromagnetic layer was Co_{0.38}Fe_{0.24}X_{0.12}Pt_{0.26}. Example 8 differs from Example 6 in that the relation of δ=0.26 is established. The other conditions were the same as in Example 6, and the same measurements as in Example 6 were performed.

The magnetization of the first ferromagnetic layer of the magnetoresistance effect element in Example 8 was oriented in the in-plane X direction under no magnetic field. The anisotropic magnetic field of the first ferromagnetic layer in the Y direction was 187 Oe. In addition, the uniaxial magnetic anisotropy energy of the first ferromagnetic layer was 7.7×10⁴ erg/cm.

### Example 9

Example 9 differs from Example 7 in that the thickness of the first ferromagnetic layer was set to 2 nm. The other conditions were the same as in Example 7, and the same measurements as in Example 7 were performed.

The magnetization of the first ferromagnetic layer of the magnetoresistance effect element in Example 9 is oriented in the in-plane X direction under no magnetic field. The anisotropic magnetic field of the first ferromagnetic layer in the Y direction was 89 Oe. In addition, the uniaxial magnetic anisotropy energy of the first ferromagnetic layer was 3.8×10⁴ erg/cm.

### Example 10

Example 10 differs from Example 7 in that the thickness of the first ferromagnetic layer was set to 8 nm. The other conditions were the same as in Example 7, and the same measurements as in Example 7 were performed.

The magnetization of the first ferromagnetic layer of the magnetoresistance effect element in Example 10 was oriented in the in-plane X direction under no magnetic field. The anisotropic magnetic field of the first ferromagnetic layer in the Y direction was 233 Oe. In addition, the uniaxial magnetic anisotropy energy of the first ferromagnetic layer was 1.4×10⁵ erg/cm.

### Example 11

Example 11 differs from Example 7 in that the thickness of the first ferromagnetic layer was set to 20 nm. The other conditions were the same as in Example 7, and the same measurements as in Example 7 were performed.

The magnetization of the first ferromagnetic layer of the magnetoresistance effect element in Example 11 was oriented in the in-plane X direction under no magnetic field. The anisotropic magnetic field of the first ferromagnetic layer in the Y direction was 145 Oe. In addition, the uniaxial magnetic anisotropy energy of the first ferromagnetic layer was 8.2×10⁴ erg/cm.

### Example 12

Example 12 differs from Example 11 in that the annealing temperature was set to 300° C. The other conditions were the same as in Example 11, and the same measurements as in Example 11 were performed.

The magnetization of the first ferromagnetic layer of the magnetoresistance effect element in Example 12 was oriented in the in-plane X direction under no magnetic field. The anisotropic magnetic field of the first ferromagnetic layer in the Y direction was 271 Oe. In addition, the uniaxial magnetic anisotropy energy of the first ferromagnetic layer was 1.5×10⁵ erg/cm.

### Example 13

Example 13 differs from Example 11 in that the annealing temperature was set to 250° C. The other conditions were the same as in Example 11, and the same measurements as in Example 11 were performed.

The magnetization of the first ferromagnetic layer of the magnetoresistance effect element in Example 13 was oriented in the in-plane X direction under no magnetic field. The anisotropic magnetic field of the first ferromagnetic layer in the Y direction was 173 Oe. In addition, the uniaxial magnetic anisotropy energy of the first ferromagnetic layer was 9.9×10⁴ erg/cm.

Hereinbefore, the above results are summarized in the following table.

TABLE 1

| | | | | | | | | | Uniaxial |
|---|---|---|---|---|---|---|---|---|---|
| | | | | | | | | Y-direction | magnetic |
| | | | | | | | Annealing | saturation | anisotropy |
| | | | | | | Thickness | temperature | magnetic | energy |
| | α | β | γ | δ | X | (nm) | (° C.) | field (Oe) | (erg/cm) |
| Example 1 | 0.4 | 0.4 | 0.2 | 0 | B | 3 | 350 | 50 | 3.6 × 10⁴ |
| Example 2 | 0.5 | 0.3 | 0.2 | 0 | B | 3 | 350 | 63 | 4.5 × 10⁴ |
| Example 3 | 0.36 | 0.36 | 0.13 | 0.15 | B | 3 | 350 | 64 | 3.6 × 10⁴ |
| Example 4 | 0.33 | 0.33 | 0.13 | 0.21 | B | 3 | 350 | 127 | 6.9 × 10⁴ |
| Example 5 | 0.31 | 0.31 | 0.12 | 0.26 | B | 3 | 350 | 145 | 6.3 × 10⁴ |
| Example 6 | 0.46 | 0.27 | 0.14 | 0.13 | B | 3 | 350 | 100 | 5.7 × 10⁴ |
| Example 7 | 0.41 | 0.26 | 0.13 | 0.20 | B | 3 | 350 | 125 | 6.6 × 10⁴ |
| Example 8 | 0.38 | 0.24 | 0.12 | 0.26 | B | 3 | 350 | 187 | 7.7 × 10⁴ |
| Example 9 | 0.41 | 0.26 | 0.13 | 0.20 | B | 2 | 350 | 89 | 3.8 × 10⁴ |
| Example 10 | 0.41 | 0.26 | 0.13 | 0.20 | B | 8 | 350 | 233 | 1.4 × 10⁵ |
| Example 11 | 0.41 | 0.26 | 0.13 | 0.20 | B | 20 | 350 | 145 | 8.2 × 10⁴ |
| Example 12 | 0.41 | 0.26 | 0.13 | 0.20 | B | 20 | 300 | 271 | 1.5 × 10⁵ |
| Example 13 | 0.41 | 0.26 | 0.13 | 0.20 | B | 20 | 250 | 173 | 9.9 × 10⁴ |
| Comparative | 0.2 | 0.6 | 0.2 | 0 | B | 3 | 350 | 25 | 1.7 × 10⁴ |
| Example 1 | | | | | | | | | |

As also illustrated in Table 1 above, Examples 1 to 12 exhibit higher uniaxial anisotropy than Comparative Example 1. Therefore, the magnetoresistance effect elements in Examples 1 to 12 exhibit excellent magnetization stability.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

### EXPLANATION OF REFERENCES

1, 91 First ferromagnetic layer
2, 92 Second ferromagnetic layer
3, 93 Nonmagnetic layer
4, 5, 94 Underlayer
6 First electrode
7 Second electrode
10, 11 Magnetoresistance effect element
20 Magnetic multilayer film
101 First switch
102 Second switch
103 Third switch
104 Fourth switch
105 Detector
110, 111 Magnetic memory
120 Magnetic sensor
L1 First wiring
L2 Second wiring
L3 Third wiring
LA Fourth wiring
L5 Fifth wiring
Wx, Wy Width

What is claimed is:

1. A method of manufacturing a magnetoresistance effect element, the method comprising:
a lamination step of laminating an underlayer, a first ferromagnetic layer, a nonmagnetic layer, and a second ferromagnetic layer in this order; and
a magnetic field application annealing step of performing annealing while applying a magnetic field in a first direction in a plane orthogonal to a lamination direction,
wherein the underlayer contains Ta,
the first ferromagnetic layer is represented by Co_{α}Fe_{β}X_{γ}Pt_{δ},
X is boron or carbon, and
the relations of α+β+γ+δ=1, α≥β>0, and δ≤0.3 are satisfied.

2. The method of manufacturing a magnetoresistance effect element according to claim 1, wherein an annealing temperature in the magnetic field application annealing step is equal to or higher than 200° C.

3. The method of manufacturing a magnetoresistance effect element according to claim 1, wherein an annealing time in the magnetic field application annealing step is equal to or longer than 30 minutes.

4. The method of manufacturing a magnetoresistance effect element according to claim 1, wherein a strength of the magnetic field applied in the magnetic field application annealing step is equal to or higher than 1 kOe.

5. The method of manufacturing a magnetoresistance effect element according to claim 1, wherein γ satisfies 0.05≤γ≤0.2.

6. The method of manufacturing a magnetoresistance effect element according to claim 1, wherein δ satisfies 0.05≤δ≤0.3.

7. The method of manufacturing a magnetoresistance effect element according to claim 1, wherein the nonmagnetic layer contains magnesium and oxygen.

8. A magnetoresistance effect element comprising: a first ferromagnetic layer, a second ferromagnetic layer, a nonmagnetic layer, and an underlayer,
wherein the nonmagnetic layer is located between the first ferromagnetic layer and the second ferromagnetic layer,
the first ferromagnetic layer is located between the underlayer and the nonmagnetic layer,
the underlayer contains Ta,
the first ferromagnetic layer is represented by Co_{α}Fe_{β}X_{γ}Pt_{δ},
X is boron or carbon,
the relations of α+β+γ+δ=1, α≥β>0, and δ≤0.3 are satisfied,
the first ferromagnetic layer has an easy axis of magnetization in a first direction in a plane orthogonal to a lamination direction,
an anisotropic magnetic field of the first ferromagnetic layer in a second direction is equal to or higher than 50 Oe, and
the second direction is orthogonal to the lamination direction and the first direction.

9. The magnetoresistance effect element according to claim 8, wherein γ satisfies 0.05≤γ≤0.2.

10. The magnetoresistance effect element according to claim 8, wherein δ satisfies 0.05≤δ≤0.3.

11. The magnetoresistance effect element according to claim 8, wherein the nonmagnetic layer contains magnesium and oxygen.

12. The magnetoresistance effect element according to claim 8, wherein a thickness of the first ferromagnetic layer is equal to or greater than 2 nm and equal to or less than 20 nm.

13. The magnetoresistance effect element according to claim 8, wherein the first ferromagnetic layer has a uniaxial magnetic anisotropy energy equal to or greater than 2.0×10⁴ erg/cm.

14. The magnetoresistance effect element according to claim 8, further comprising a first electrode and a second electrode,
wherein the first electrode is connected to a first end of the underlayer, and
the second electrode is connected to a second end of the underlayer which is different from the first end.

15. The magnetoresistance effect element according to claim 8, wherein, in a plan view from the lamination direction, a width of the first ferromagnetic layer in the first direction is equal to or greater than 90% and equal to or less than 110% of a width of the first ferromagnetic layer in the second direction.

16. A magnetic multilayer film comprising an underlayer and a first ferromagnetic layer,
wherein the underlayer is in contact with one surface of the first ferromagnetic layer,
the underlayer contains Ta,
the first ferromagnetic layer is represented by Co_{α}Fe_{β}X_{γ}Pt_{δ},
X is boron or carbon,
the relations of α+β+γ+δ=1, α≥β>0, 0.05≤γ≤0.2, and 0.05≤δ≤0.3 are satisfied,
the first ferromagnetic layer has an easy axis of magnetization in a first direction in a plane orthogonal to a lamination direction,
an anisotropic magnetic field of the first ferromagnetic layer in a second direction is equal to or higher than 50 Oe, and
the second direction is orthogonal to the lamination direction and the first direction.

17. A magnetic memory comprising the magnetoresistance effect element according to claim 8.

18. A magnetic sensor comprising the magnetoresistance effect element according to claim 8.
